(19) United States
(12) Patent Application Publication
(10) Pub. No.: US 2021/0125839 A1
(43) Pub. Date: Apr. 29, 2021

(54) FLUID SUPPLY DEVICE AND FLUID SUPPLY METHOD

(71) Applicant: FUJIKIN INCORPORATED, Osaka (JP)

(72) Inventors: Toshihide YOSHIDA, Osaka (JP); Yukio MINAMI, Osaka (JP); Tsutomu SHINOHARA, Osaka (JP)

(73) Assignee: FUJIKIN INCORPORATED, Osaka (JP)

(21) Appl. No.: 16/634,673

(22) PCT Filed: Jul. 31, 2018
(86) PCT No.: PCT/JP2018/028592

§ 371 Date: Jan. 28, 2020

(30) Foreign Application Priority Data
Aug. 10, 2017 (JP) 2017-156177

(51) Int. Cl. H01L 21/67; H01L 21/02

(52) U.S. Cl. CPC H01L 21/6715; H01L 21/02052

(57) ABSTRACT

A fluid supply device and a fluid supply method capable of stably supplying a supercritical fluid includes a fluid supply device for supplying a fluid in a liquid state before being changed to a supercritical fluid toward a processing chamber. The fluid supply device comprises a condenser that condenses and liquefies carbon dioxide in a gas state, a tank that stores the fluid condensed and liquefied by the condenser, a pump that pressure-feeds the liquefied carbon dioxide stored in the tank toward the processing chamber, and a damper part that is provided to a flow path communicating with a discharge side of the pump and suppresses periodic pressure fluctuations of the liquid discharged from the pump. The damper part includes a spiral tube formed into a spiral shape that is fixed at both end portions in predetermined positions, and allows the liquid discharged from the pump to flow therethrough.

### FIELD OF THE INVENTION

The present invention relates to a fluid supply device and a fluid supply method used in a drying process or the like of various substrates, such as semiconductor substrates, photo mask glass substrates, and liquid crystal display glass substrates.

### DESCRIPTION OF THE BACKGROUND ART

A large-scale, high-density, high-performance semiconductor device is manufactured through processes such as coating, etching, rinsing, and drying after formation of patterns on a resist formed on a silicon wafer through exposure, development, rinsing, and drying. In particular, a resist of a polymer material is a polymer material sensitive to light, X-rays, electron beams, and the like. In each process, chemical solutions such as a developer and a rinsing solution are used in the development and rinsing processes, and therefore a drying process is essential after the rinsing process.

In this drying process, when a space width between patterns formed on the resist substrate is about 90 nm or less, the problem arises that a Laplace force acts between the patterns due to a surface tension (capillary force) of the chemical solution remaining between the patterns, causing the patterns to collapse. To prevent pattern collapse caused by the action of the surface tension of the chemical solution remaining between patterns, methods of using a supercritical fluid of carbon dioxide as a drying process to reduce the surface tension acting between the patterns are known (Patent Documents 1 to 4, for example).

### PATENT DOCUMENTS

### Patent Document 1: Japanese Laid-Open Patent Application No. 2014-22520

### Patent Document 2: Japanese Laid-Open Patent Application No. 2006-294662

### Patent Document 3: Japanese Laid-Open Patent Application No. 2004-335675

### Patent Document 4: Japanese Laid-Open Patent Application No. 2002-33302

### SUMMARY OF THE INVENTION

### Problems to be Solved by the Invention

Supplying the supercritical fluid of carbon dioxide to the processing chamber is performed by condensing and liquefying carbon dioxide (for example, 20° C., 5.0 MPa) in a gas state from a supply source using a condenser, storing the condensed and liquefied carbon dioxide in a tank, and pressure-feeding the condensed and liquefied carbon dioxide to the processing chamber using a pump (for example, 20° C., 20.0 MPa). The carbon dioxide in a liquid state fed to the processing chamber is heated (for example, 80° C., 20.0 MPa) right before the processing chamber or inside the processing chamber to form a supercritical fluid.

Nevertheless, because the carbon dioxide in a liquid state is pressure-fed by the pump in pulsated manner, the pressure of the liquid fluctuates greatly. Thus, a supply amount of carbon dioxide that changes to a supercritical state right before the processing chamber or inside the processing chamber becomes unstable, making it difficult to stably supply the supercritical fluid of carbon dioxide.

An object of the present invention is to provide a fluid supply device and a fluid supply method capable of stably supplying a supercritical fluid.

### Means for Solving the Problems

A fluid supply device of the present invention is a fluid supply device for supplying a fluid in a liquid state toward a processing chamber, and comprises:

a condenser that liquefies a fluid in a gas state,

a tank that stores the fluid liquefied by the condenser,

a pump that pressure-feeds the liquefied fluid stored in the tank toward the processing chamber, and

a damper part that communicates with a flow path on a discharge side of the pump and suppresses a pressure fluctuation of the liquid discharged from the pump.

The damper part includes a current-transforming tube part fixed at both end portions in predetermined positions and formed to change a direction of flow of the liquid between the both end portions.

Preferably, a configuration can be adopted in which the damper part is provided to a flow path that branches from an area on an upstream side of a switch valve provided in a middle of a flow path from the discharge side of the pump to the processing chamber, and is for returning the liquid discharged from the pump to the condenser.

More preferably, a configuration can be adopted in which the condenser, the tank, the pump, and the switch valve are provided to a main flow path that connects a fluid supply source that supplies the fluid in a gas state and the processing chamber,

the damper part is provided to a branching flow path that branches from an area between the pump and the switch valve and is connected to the main flow path upstream of the condenser,

the fluid in a liquid state pressure-fed from the pump returns to the condenser and the tank again through the branching flow path when the switch valve is closed, and

the fluid in a liquid state is pressure-fed to the processing chamber and heated by a heating unit provided right before the processing chamber or inside the processing chamber to be changed to a supercritical state when the switch valve is opened.

A fluid supply method of the present invention comprises a step of using the fluid supply device having the above-described configuration to supply a fluid in a liquid state toward a processing chamber.

A semiconductor manufacturing system of the present invention comprises the fluid supply device having the above-described configuration, and

a processing chamber that processes a substrate using a fluid supplied from the fluid supply device.

A semiconductor manufacturing method of the present invention comprises a step of using the fluid supply device having the above-described configuration to process a substrate.

### EFFECT OF THE INVENTION

According to the present invention, it is possible to absorb a pulsation of a fluid pressure-fed by a pump and suppress a pressure fluctuation of a fluid in a liquid state by a damper part, and thus stably supply a supercritical fluid to a processing chamber.

### BRIEF DESCRIPTION OF THE DRAWINGS

FIG. 1A is a configuration diagram of a fluid supply device according to an embodiment of the present invention, and is a diagram illustrating a state in which a fluid is circulating.

FIG. 1B is a diagram illustrating a state in which a liquid is supplied to a processing chamber in the fluid supply device of FIG. 1A.

FIG. 2 is a graph showing a state of carbon dioxide.

FIG. 3 is a front view illustrating an example (spiral tube) of a damper part.

FIG. 4A is a schematic configuration view illustrating another embodiment of the damper part.

FIG. 4B is a schematic configuration view illustrating yet another embodiment of the damper part.

### DESCRIPTION OF THE PREFERRED EMBODIMENTS

Embodiments of the present invention are described below with reference to the drawings.

### First Embodiment

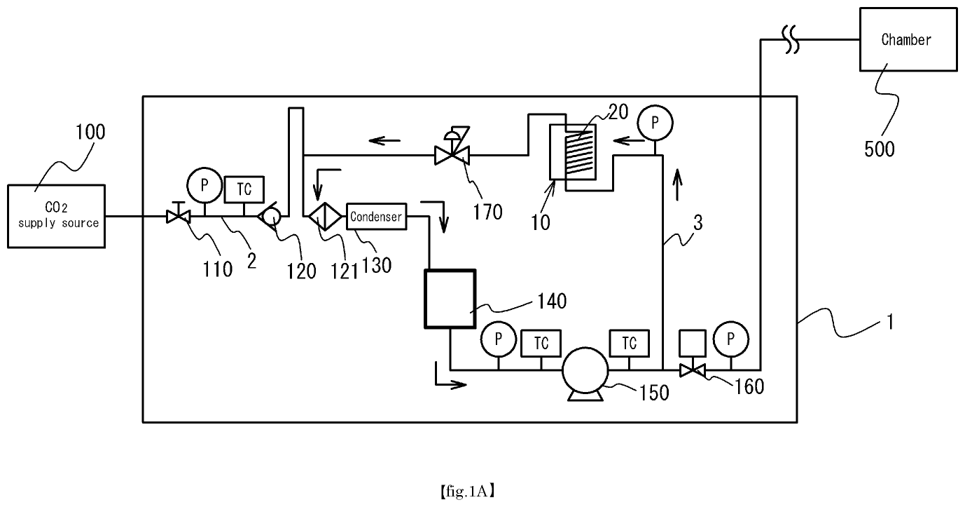

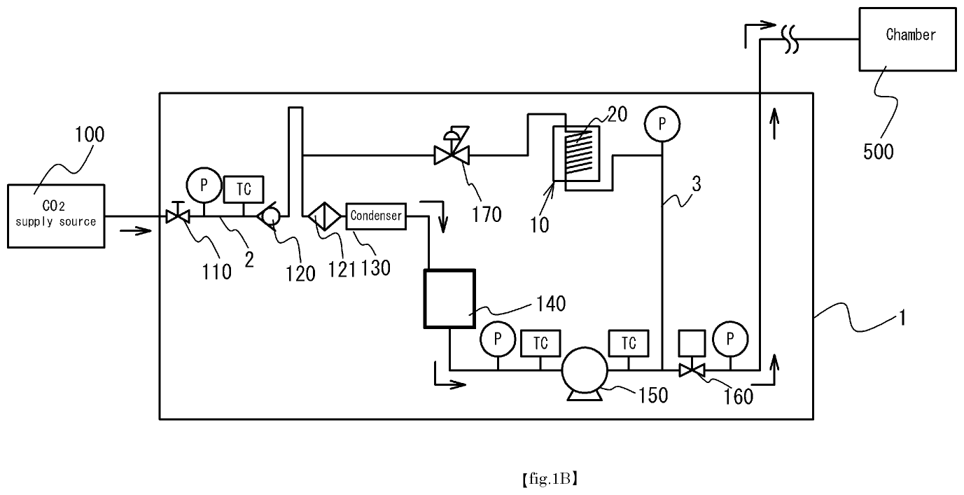

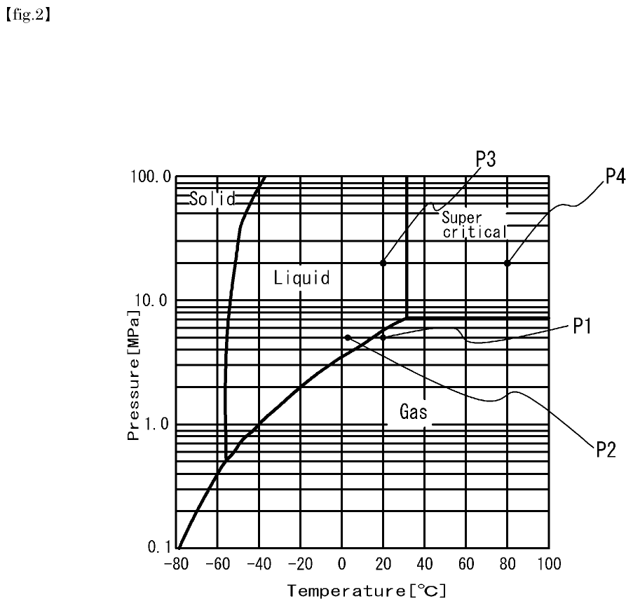

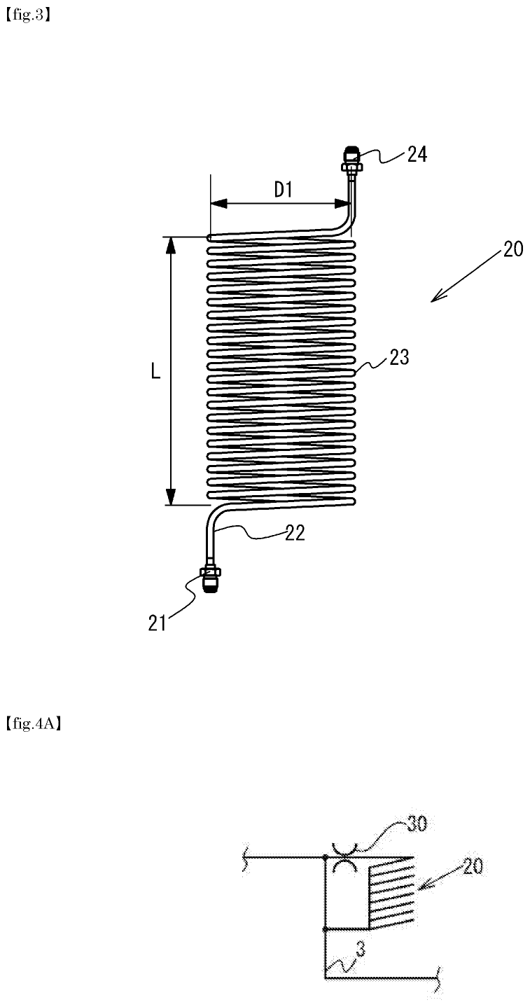

FIG. 1A and FIG. 1B illustrate a fluid supply device according to an embodiment of the present invention. In the present embodiment, a case in which carbon dioxide is used as the fluid will be described.

In FIG. 1A and FIG. 1B, 1 denotes a fluid supply device, 10 denotes a damper part, 20 denotes a spiral tube, 100 denotes a CO₂ supply source, 110 denotes a switch valve, 120 denotes a check valve, 121 denotes a filter, 130 denotes a condenser, 140 denotes a tank, 150 denotes a pump, 160 denotes an automatic switch valve, 170 denotes a back pressure valve, and 500 denotes a processing chamber. Further, in the drawings, P denotes a pressure sensor, and TC denotes a temperature sensor. FIG. 1A illustrates a state in which the automatic switch valve 160 is closed, and FIG. 1B illustrates a state in which the automatic switch valve 160 is opened.

In the processing chamber 500, a semiconductor substrate such as a silicon wafer is processed. It should be noted that while, in the present embodiment, a silicon wafer is exemplified as a processing target, the processing target is not necessarily limited thereto, and may be another processing target such as a glass substrate.

The CO₂ supply source 100 supplies carbon dioxide (for example, 20° C., 5.0 MPa) in a gas state to a main flow path 2. With reference to FIG. 2, the carbon dioxide supplied from the CO₂ supply source 100 is in a state of P1 in FIG. 2. The carbon dioxide in this state is fed to the condenser 130 through the switch valve 110, the check valve 120, and the filter 121.

In the condenser 130, the supplied carbon dioxide in a gas state is cooled and thus liquefied and condensed, and the liquefied and condensed carbon dioxide is stored in the tank 140. The carbon dioxide stored in the tank 140 is in a state (3° C., 5 MPa) such as indicated by P2 in FIG. 2. The carbon dioxide in a liquid state such as indicated by P2 in FIG. 2 is fed from a bottom portion of the tank 140 to the pump 150 and pressure-fed to a discharge side of the pump 150, and thus changes to a liquid state (20° C., 20 MPa) such as indicated by P3 in FIG. 2.

The automatic switch valve 160 is provided in a middle of the main flow path 2 connecting the pump 150 and the processing chamber 500. A branching flow path 3 branches from an area between the pump 150 and the automatic switch valve 160 of the main flow path 2. The branching flow path 3 branches from the main flow path 2 between the pump 150 and the automatic switch valve 160, and is connected to the main flow path 2 again on an upstream side of the filter 121. The damper part 10 and the back pressure valve 170 are provided to the branching flow path 3.

When a pressure of the fluid (liquid) on the discharge side of the pump 150 becomes a setting pressure (for example, 20 MPa) or greater, the back pressure valve 170 releases the liquid to the filter 121 side. Accordingly, the pressure of the liquid on the discharge side of the pump 150 is prevented from exceeding the setting pressure.

With the automatic switch valve 160 closed, the liquid pressure-fed from the pump 150 returns again to the condenser 130 and the tank 140 through the branching flow path 3, as illustrated in FIG. 1A.

When the automatic switch valve 160 is opened, the carbon dioxide in a liquid state is pressure-fed to the processing chamber 500, as illustrated in FIG. 1B. The carbon dioxide in a liquid state thus pressure-fed is heated by a heater (not illustrated) provided right before the processing chamber 500 or inside the processing chamber 500, and turns into a supercritical state (80° C., 20 MPa) such as indicated by P4 illustrated in FIG. 2.

Here, the liquid discharged from the pump 150 pulsates considerably.

When the liquid discharged from the pump 150 is supplied to the processing chamber 500, the main flow path 2 is filled with the liquid up to the processing chamber 500, and the branching flow path 3 is also filled with liquid up to the back pressure valve 170. Thus, when the liquid discharged from the pump 150 pulsates, the pressure of the carbon dioxide in a liquid state in the main flow path 2 and the branching flow path 3 periodically fluctuates.

Carbon dioxide in a liquid state has poor compressibility. Thus, when the pressure of the carbon dioxide in a liquid state periodically fluctuates, a flow rate of the carbon dioxide in a liquid state supplied to the processing chamber 500 also greatly fluctuates accordingly. When the flow rate of the supplied carbon dioxide in a liquid state greatly fluctuates, a supply amount of the carbon dioxide changed to the supercritical state right before the processing chamber 500 or inside the processing chamber 500 also greatly fluctuates.

Thus, in the present embodiment, the damper part 10 is provided to the branching flow path 3, the pulsation of the liquid discharged from the pump 150 is dampened, and the periodic pressure fluctuations of the liquid discharged from the pump 150 are suppressed to stabilize the supply amount of the carbon dioxide changed to the supercritical state.

The damper part 10 includes a flow-changing tube part fixed at both end portions in predetermined positions and formed to change a direction of flow of the liquid between the both end portions, and the spiral tube 20 connected in series to the branching flow path 3, as illustrated in FIG. 3.

It should be noted that, in addition to the spiral tube, the current-transforming tube part may be a helical tube, a corrugated tube, a serpentine tube, or the like. The spiral or helical shape need not be circular, and may be square.

The spiral tube 20 is provided with pipe joints 21, 24 at a lower end portion and an upper end portion, respectively, and is connected in series to the branching flow path 3 by these pipe joints 21, 24.

A tube 22 constituting the spiral tube 20 is formed of a metal material such as stainless steel, for example. A diameter of the tube 22 is 6.35 mm, a total length L of a spiral part 23 is 280 mm, a diameter D1 of the spiral part 23 is about 140 mm, a number of turns of the spiral part 23 is 22, and a total length of the tube 22 is about 9,800 mm.

According to an experiment by the present inventors, it was found that the spiral tube 20 fixed at both end portions vibrates (elastically deforms) in accordance with a pressure fluctuation of the liquid when the pressure of the liquid filled in the interior fluctuates. That is, it is presumed that, when the liquid pulsates, energy is consumed by the spiral tube 20, causing a damper action that suppresses the pulsation (pressure fluctuation) of the liquid discharged from the pump 150 to be exhibited.

As a result, it was possible to stabilize the supply amount of carbon dioxide changed to a supercritical state right before the processing chamber 500 or inside the processing chamber 500.

### Second Embodiment

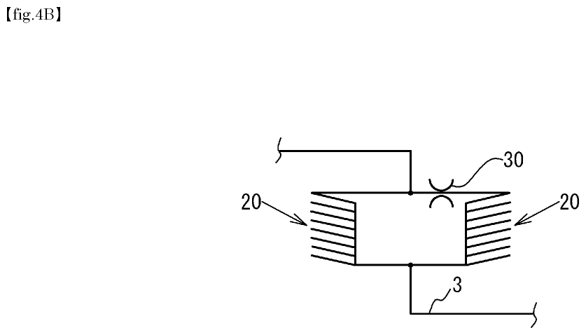

FIG. 4A illustrates another embodiment of the damper part.

In the damper part illustrated in FIG. 4A, the spiral tube 20 is connected in parallel to the branching flow path 3, and an orifice 30 is provided between the branching flow path 3 and the spiral tube 20.

Even with such a configuration, in the same way as in the first embodiment, it is possible to suppress the pulsation (periodic pressure fluctuation) of the liquid discharged from the pump 150, and stabilize the supply amount of carbon dioxide changed to a supercritical state right before the processing chamber 500 or inside the processing chamber 500.

### Third Embodiment

FIG. 4B illustrates yet another embodiment of the damper part.

In the damper part illustrated in FIG. 4B, two of the spiral tubes 20 are connected in parallel and inserted into the branching flow path 3, and the orifice 30 is provided between the branching flow path 3 and one of the spiral tubes 20.

Even with such a configuration, in the same way as in the first embodiment, it is possible to suppress the pulsation (periodic pressure fluctuation) of the liquid discharged from the pump 150, and stabilize the supply amount of carbon dioxide changed to a supercritical state right before the processing chamber 500 or inside the processing chamber 500.

While a case in which the damper part 10 is provided to the branching flow path 3 is given as an example in each of the above-described embodiments, the present invention is not necessarily limited thereto, and the damper part 10 can be provided to the main flow path 2 on the discharge side of the pump 150 as well.

While carbon dioxide is illustrated as the fluid in the above-described embodiments, the present invention is not necessarily limited thereto and is applicable as long as the fluid can be changed to a supercritical state.

### DESCRIPTIONS OF REFERENCE NUMERALS

1 Fluid supply device

2 Main flow path

3 Branching flow path

10 Damper part

20 Spiral tube

30 Orifice

100 CO₂ supply source

110 Switch valve

120 Check valve

121 Filter

130 Condenser

140 Tank

150 Pump

160 Automatic switch valve

170 Back pressure valve

500 Processing chamber

1. A fluid supply device for supplying a fluid in a liquid state toward a processing chamber, comprising:
a condenser that liquefies a fluid in a gas state;
a tank that stores the fluid liquefied by the condenser;
a pump that pressure-feeds the liquefied fluid stored in the tank toward the processing chamber; and
a damper part that communicates with a flow path on a discharge side of the pump and suppresses a pressure fluctuation of the liquid discharged from the pump,
the damper part including a flow-changing tube part fixed at both end portions in predetermined positions and formed to change a direction of flow of the liquid between the both end portions.

2. The fluid supply device according to claim 1, wherein
the damper part is provided to a flow path that branches from an area between the pump and a switch valve provided in a middle of a flow path from the discharge side of the pump to the processing chamber, the flow path thus branched being a flow path for returning the liquid discharged from the pump to the condenser.

3. The fluid supply device according to claim 2, wherein
the condenser, the tank, the pump, and the switch valve are provided to a main flow path that connects a fluid supply source that supplies the fluid in a gas state and the processing chamber,
the damper part is provided to a branching flow path that branches from an area between the pump and the switch valve and is connected to the main flow path upstream of the condenser,
the fluid in a liquid state pressure-fed from the pump returns to the condenser and the tank again through the branching flow path when the switch valve is closed, and
the fluid in a liquid state is pressure-fed to the processing chamber and heated by a heating unit provided right before the processing chamber or inside the processing chamber to be changed to a supercritical state when the switch valve is opened.

4. The fluid supply device according to claim 3, wherein
the damper part is provided to suppress a pressure fluctuation of a liquid discharged from the pump when the switch valve is opened.

5. The fluid supply device according to claim 3, wherein
the main flow path is provided with a check valve that prevents a back flow of the fluid to the fluid supply source side upstream of a connecting part with the branching flow path on the upstream side of the condenser.

6. The fluid supply device according to claim 1, wherein
the current-transforming tube part includes any one of a spiral tube, a helical tube, a corrugated tube, and a serpentine tube.

7. The fluid supply device according to claim 1, wherein
the fluid includes carbon dioxide.

8. A fluid supply method comprising a step of using the fluid supply device described in claim 1 to supply a fluid in a liquid state toward a processing chamber.

9. A semiconductor manufacturing system comprising:
the fluid supply device described in claim 1; and
a processing chamber that processes a substrate using a fluid supplied from the fluid supply device.

10. (canceled)
